(19) United States
(12) Patent Application Publication
(10) Pub. No.: US 2018/0192193 A1
(43) Pub. Date: Jul. 5, 2018

(54) SOUND ADJUSTMENT DEVICE FOR HEARING PROTECTION AND SOUND ADJUSTMENT METHOD THEREOF

(71) Applicant: Unlimiter MFA Co., Ltd., Eden Island (SC)

(72) Inventors: Kuan-Li CHAO, Taipei (TW); Kuo-Ping YANG, Taipei (TW); Neo Bob Chih-Yung YOUNG, Taipei (TW); Chih-Long CHANG, Taipei (TW); Hsiang-Chun KO, Taipei (TW); Jian-Ying LI, Taipei (TW); Wei-Lin CHANG, Taipei (TW)

(21) Appl. No.: 15/497,438

(22) Filed: Apr. 26, 2017

(30) Foreign Application Priority Data
Jan. 5, 2017 (TW) 106100343

(51) Int. Cl. H04R 3/04; H03G 3/30

(52) U.S. Cl. CPC H04R 3/04; H03G 3/3005

(57) ABSTRACT

A sound adjustment device for hearing protection and a sound adjustment method thereof are disclosed. The method includes: acquiring a sound signal, wherein the sound signal includes a plurality of frequency bands, each frequency band corresponds to a volume; analyzing whether the volume exceeds a setting condition; reducing a gain value of the frequency band which is exceeded the setting condition for reducing the volume of the frequency band and generating an adjusted sound signal; and outputting the adjusted sound signal.

### BACKGROUND OF THE INVENTION

### 1. Field of the Invention

The present invention relates to a sound adjustment device having a hearing protection function and a sound adjustment method thereof, particularly to a sound adjustment device having a hearing protection function and a sound adjustment method thereof that can adjust a gain value automatically.

### 2. Description of the Related Art

Nowadays, people often listen to music with headsets to achieve better listening effect. However, earphone may have greater impact on user's hearing. Continued excessive volume is likely to cause hearing loss. Therefore, a method of automatically controlling volume has been developed now. Currently, headset volume is automatically controlled by adjusting the volume of a sound signal directly. There is no specific function for adjusting the volume of sound signals in different frequency bands.

Accordingly, it is necessary to invent a new sound adjustment device having hearing protection function and a sound adjustment method thereof to solve the problem in the prior art.

### SUMMARY OF THE INVENTION

It is a major objective of the present invention to provide a sound adjustment device having a hearing protection function, which provides the effect of automatically adjusting a gain value.

It is another objective of the present invention to provide a sound adjustment method used in the sound adjustment device.

To achieve the objectives described above, a sound adjustment device according to the present invention is used for adjusting a sound signal. The sound adjustment device comprises an input end, an analysis module, an adjustment module, and an output end. The input end is used for acquiring a sound signal, wherein the sound signal includes a plurality of frequency bands, and each of the frequency bands corresponds to a volume. The analysis module is electrically connected to the input for analyzing whether each volume exceeds the setting condition. The adjustment module is electrically connected to the analysis module for reducing a gain value of the sound in a frequency band that exceeds the setting condition for reducing the volume of the frequency band and generating an adjusted sound signal. The output end is electrically connected to the adjustment module for outputting adjusted sound signal.

The sound adjustment method in the present invention comprises the following steps: acquiring a sound signal, wherein the sound signal includes a plurality of frequency bands, each frequency band corresponds to a volume; analyzing whether the volume exceeds a setting condition; reducing a gain value of the frequency band which is exceeded the setting condition for reducing the volume of the frequency band and generating an adjusted sound signal; and outputting the adjusted sound signal.

### BRIEF DESCRIPTION OF THE DRAWINGS

FIG. 1 is an architecture diagram of a sound adjustment device in the present invention;

FIG. 1A is a schematic diagram of a sound adjustment device in a first embodiment of the present invention;

FIG. 1B is a schematic diagram of a sound adjustment device in a second embodiment of the present invention;

FIG. 1C is a schematic diagram of a sound adjustment device in a third embodiment of the present invention;

FIG. 2A is a graph showing volumes of sound signals in different frequency bands according to the present invention;

FIG. 2B shows the use of a sound adjustment device for sound adjustment according to the present invention; and

FIG. 3 is a flowchart showing a sound adjustment method in the present invention.

### DETAILED DESCRIPTION OF THE PREFERRED EMBODIMENT

Hereafter, the technical content of the present invention will be better understood with reference to preferred embodiments.

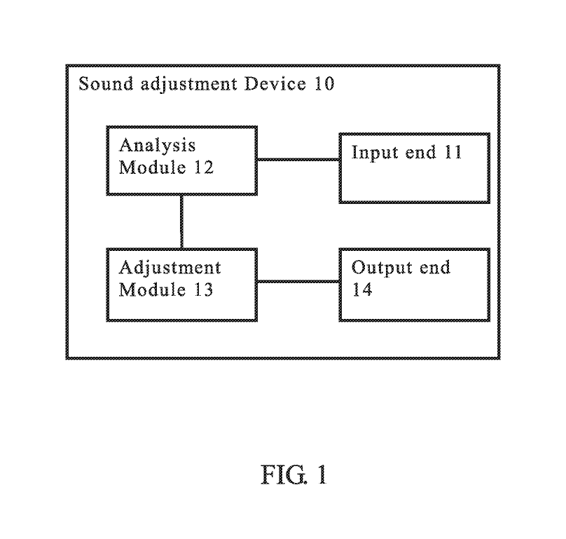

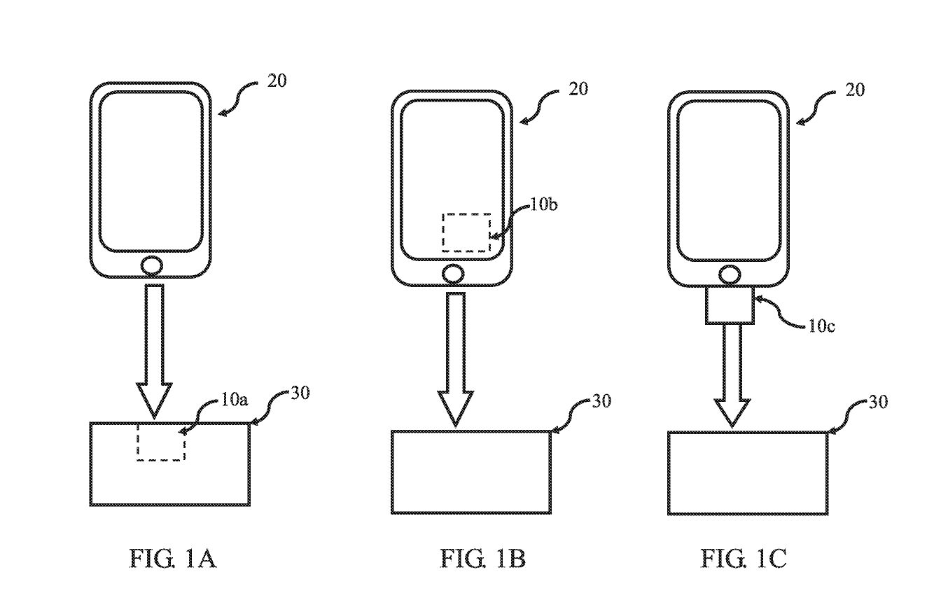

Please first refer to FIG. 1 which is an architecture diagram of a sound adjustment device in the present invention.

A sound adjustment device 10 having a hearing protection function in the present invention is used for adjusting a sound signal generated by a sound generation device 20. As the sound is made by the speaker 30, this can avoid the user's hearing damage. The sound generation device 20 may be a device capable of generating a sound signal, such as a television or audio device. The speaker 30 may be an earphone device or a speaker, but the present invention is not limited to the devices listed above. The sound generation device 20 may emit a variety of sounds with varying volumes. If a large volume is often heard, it is likely to cause the user's hearing damage.

Please refer to FIGS. 1A to 1C respectively, wherein FIG. 1A is a schematic diagram of a sound adjustment device in a first embodiment of the present invention; FIG. 1B is a schematic diagram of a sound adjustment device in a second embodiment of the present invention; and FIG. 1C is a schematic diagram of a sound adjustment device in a third embodiment of the present invention.

As shown in FIG. 1A, the sound adjustment device 10a is disposed in the speaker 30, and an input end 11 is connected to the sound generation device 20 for receiving a sound signal. The sound adjustment device 10b as shown in FIG. 1B is disposed in the sound generation device 20, and an output end 14 transmits the adjusted sound signal to the speaker 30. At last, the sound adjustment device 10c as shown in FIG. 1C is connected between the sound generation device 20 and the speaker 30, such that the input end 11 is connected with the output end 14 for signal transmission.

The sound adjustment device 10 includes an input end 11, an analysis module 12, an adjustment module 13, and an output end 14. The input end 11 is used to connect with the sound generation device 20 in a wired or wireless manner for acquiring the sound signal generated by the sound generation device 20. The sound signal will have a different volume in different frequency bands. The analysis module 12 is electrically connected to the input end 11 for analyzing the sound signal with different frequency bands of volumes to see if the volume exceeds a setting condition.

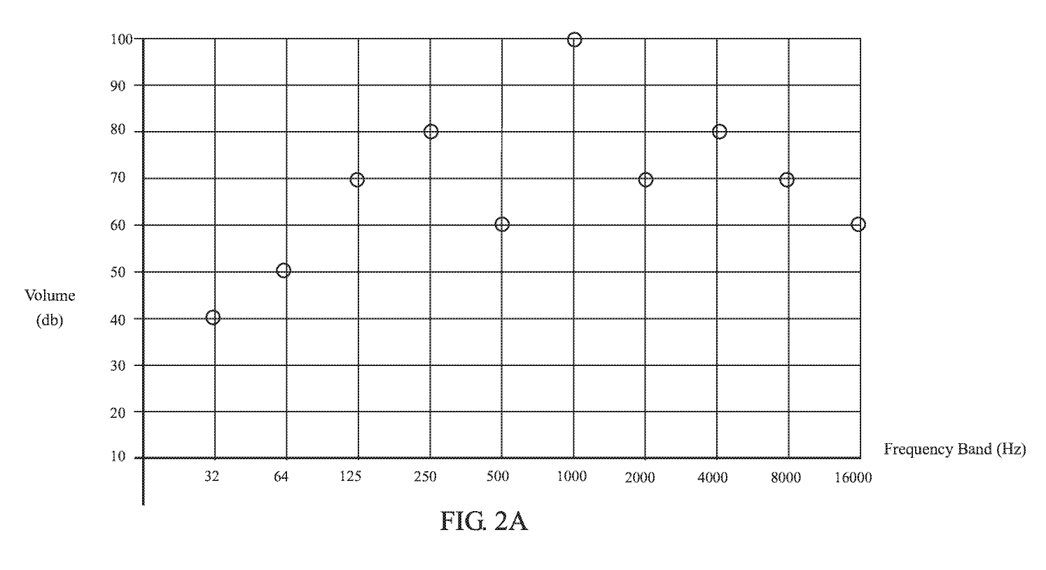

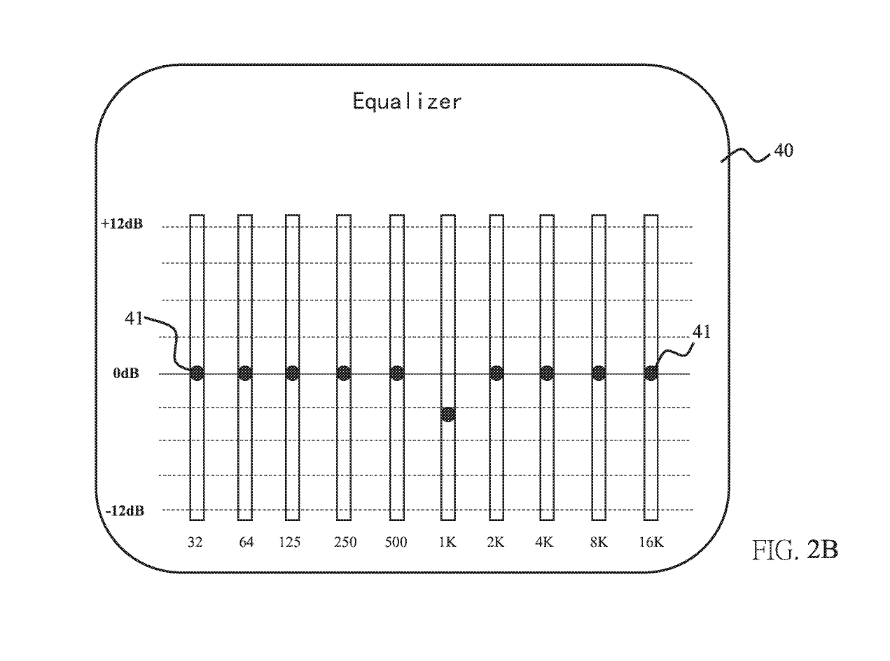

In an embodiment of the present invention, the analysis module 12 analyzes the gain value of sound signal in the frequency bands including 32 Hz, 64 Hz, 125 Hz, 250 Hz, 500 Hz, 1 KHz, 2 KHz, 4 KHz, 8 KHz and 16 KHz, but the present invention is not limited to the frequency band distribution. Also, the present invention may have different setting conditions in different embodiments, as shown in FIG. 2. FIG. 2 shows volumes of sound signals in different frequency bands according to the present invention. In an embodiment of the present invention, the setting conditions include a volume threshold, which is ranged from 60 dBA to 150 dBA. The conversion formula between the measurement unit dBFS of the signal volume and the actual output dBA may vary depending on different devices and the user's listening distance, which will be described hereafter as dBA for easy interpretation. When the volume exceeds the volume threshold, the setting condition is exceeded. The setting conditions may also comprise a cumulative time threshold, which is ranged from 1 second to 2 hours. The setting condition is exceeded when the volume exceeds the volume threshold and exceeds the cumulative time threshold. Also, in another embodiment of the present invention, when the volume threshold is larger, the cumulative time threshold may be smaller, and when the volume threshold is smaller, the cumulative time threshold may be lager. Or the cumulative time threshold that exceeds the volume threshold within a specific time interval is set as the setting condition, for example, the setting condition that more than 80 db of progressive time within 1 hour reaches 15 minutes. Or the setting condition that the number of times exceeding the volume threshold within a specific time interval, but the present invention is not limited to the aforementioned embodiments. Also, in different embodiments of the present invention, different frequency bands of the sound signal may correspond to different or same setting conditions. For example, the adjustment module 13 may set the volume threshold of all frequency bands as 80 dBA, or set the volume threshold of 4 KHz as 80 dBA and the volume threshold of 2 KHz as 90 dBA. Each frequency band has a different set threshold to dynamically adjust a different frequency band. The above setting condition is for illustration only, but the present invention is not limited thereto.

The adjustment module 13 is electrically connected to the analysis module 12. The adjustment module 13 is an equalizer (EQ), which is used for adjusting the gain value of a specific frequency band to generate an adjusted sound signal. Hereafter please also refer to FIG. 2B which is a graphic showing adjustment through the sound adjustment device in the present invention. The equalizer is a tool that can be used to adjust the sound output, which can change the gain value of the sound under different frequency bands, and thus is often used to adjust the output sound. Through adjusting the gain value of the sound under different frequency bands, the auditory effect of the output sound may be changed. Therefore, in the embodiment of the present invention as shown in FIG. 1B or FIG. 1C, the adjustment module 13 can further show an equalizer interface 40 on a display of the sound generation device 20. The equalizer interface 40 has a different adjustment button 41 depending on the frequency band. For example, when the analysis module 12 detects that the sound signal in the frequency band of 4 KHz exceeds 100 dBA, and when the sound signal in the frequency band of 4 KHz exceeds 100 dBA for 1 min, the adjustment module 13 automatically decreases the frequency band of the adjustment button 41 with the sound signal at 4 KHz, such that the frequency band is decreased below 100 dBA. Similarly, the adjustment module 13 would not adjust the frequency band if the volume of the sound signal in a certain frequency band did not exceed the setting condition.

In this way, when one of a volume of the sound signal in each of the frequency bands exceeds the setting condition, the adjustment module 13 will adjust the gain value of the sound signal in the frequency band for reducing the volume of the frequency band and generating an adjusted sound signal. Finally, the output end 14 is electrically connected to the adjustment module 13 for outputting the adjusted sound signal to the listener.

It should be noted that each module in the sound adjustment device 10 may be configured as a hardware device, software program in combination with hardware device, or firmware in combination with hardware device, but the present invention is not limited in the manner described above. Additionally, the preferred embodiment of the present invention described here is only illustrative. To avoid redundancy, all the possible combinations of changes are not documented in detail. However, it shall be understood by those skilled in the art that each of the modules or elements described above may not be necessary. For the implementation of the present invention, the present invention may also contain other detailed, conventional modules or elements. Each module or component is likely to be omitted or modified depending on the needs. Other modules or elements may not necessarily exist between two of any modules.

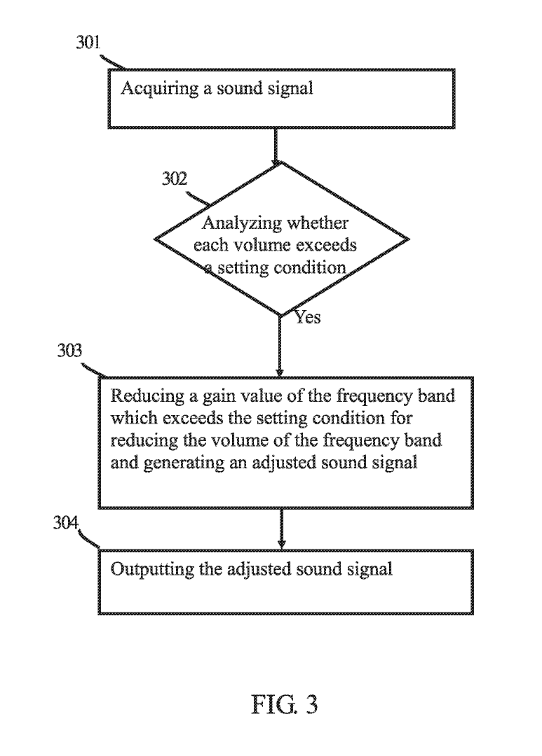

Then, please refer to FIG. 3 which is a flowchart showing steps of a sound adjustment method in the present invention. It should be noted here that although the sound adjustment device 10 is described as an example of the present invention, the sound adjustment method in the present invention is not limited to the sound adjustment device 10 using the same structure described above.

At first, in Step 301: Acquiring a sound signal.

First, the input 14 is connected to the sound generation device 20 in a wired or wireless manner for acquiring the sound signal generated by the sound generation device 20. Specifically, the sound signal includes a plurality of frequency bands, and each of the frequency bands corresponds to a volume.

Then, in Step 302: Analyzing whether the volume exceeds a setting condition.

Then, the analysis module 12 is used for analyzing the volume of the sound signal in different frequency bands, for example, analyzing the volume of the sound signal at 32 Hz, 64 Hz, 125 Hz, 250 Hz, 500 Hz, 1 KHz, 2 KHz, 4 KHz, 8 KHz and 16 KHz frequency band, but the present invention is not limited to the frequency band distribution. The setting conditions may include a volume threshold, a cumulative time threshold, or a cumulative time threshold that exceeds the volume threshold within a specific time interval, or the number of times that exceeds the volume threshold within a specific time interval, or any other setting conditions such as when the volume threshold is larger, the cumulative time threshold is smaller, and when the volume threshold is smaller, the cumulative time threshold is larger. Moreover, different frequency bands of the sound signal can correspond to different or same setting conditions, but the present invention is not limited thereto.

Next, in Step 303: Reducing a gain value of the frequency band that exceeds the setting condition for reducing the volume of the frequency band and generating an adjusted sound signal.

In this way, when a volume of the sound signal in each of the frequency bands exceeds a setting condition in Step 302, the adjustment module 13 adjusts the sound signal by reducing the gain value of the frequency band to acquire an adjusted sound signal.

Finally, in Step 304: Outputting the adjusted sound signal.

At last, the output 14 is used for outputting the adjusted sound signal to the speaker 30.

In this way, the sound adjustment device 10 can adjust the gain value of sound in a different frequency band to achieve better hearing protection effect.

It should be noted that the preferred embodiments of the present invention described above are only illustrative. To avoid redundancy, all the possible combinations of changes are not documented in detail. However, it shall be understood by those skilled in the art that each of the modules or elements described above may not be necessary. For the implementation of the present invention, the present invention may also contain other detailed, conventional modules or elements. Each module or component is likely to be omitted or modified depending on the needs. Other modules or elements may not necessarily exist between two of any modules. All without departing from the scope of the invention are defined solely by the appended claims.

What is claimed is:

1. A sound adjustment method, used in a sound adjustment device for adjusting a sound signal, the method comprising:
acquiring a sound signal, wherein the sound signal comprises a plurality of frequency bands, each frequency band corresponding to a volume;
analyzing whether the volume exceeds a setting condition;
reducing a gain value of the frequency band which exceeds the setting condition for reducing the volume of the frequency band and generating an adjusted sound signal; and
outputting the adjusted sound signal

2. The sound adjustment method as claimed in claim 1, wherein the volume of the frequency band that did not exceed the setting condition is not reduced.

3. The sound adjustment method as claimed in claim 2, wherein the setting condition includes a volume threshold ranged from 60 dBA to 150 dBA.

4. The sound adjustment method as claimed in claim 3, wherein the setting condition includes a cumulative time threshold ranged from 1 second to 2 hours.

5. The sound adjustment method as claimed in claim 4, wherein when the volume threshold is larger, the cumulative time threshold is smaller, and when the volume threshold is smaller, the cumulative time threshold is larger.

6. The sound adjustment method as claimed in claim 4, wherein the setting condition is the cumulative time threshold that exceeds the volume threshold within a specific time interval.

7. The sound adjustment method as claimed in claim 3, wherein the setting condition is the number of times that exceeds the volume threshold within a specific time interval.

8. The sound adjustment method as claimed in claim 1, further comprising letting the volume of each said frequency band correspond to the same setting condition.

9. The sound adjustment method as claimed in claim 1, further comprising letting the volume of each said frequency band correspond to a different setting condition.

10. A sound adjustment device having a hearing protection function, used for adjusting a sound signal, the sound adjustment device comprising:
an input end, for acquiring the sound signal, the sound signal comprising a plurality of frequency bands, each of the frequency bands corresponding to a volume;
an analysis module, electrically connected to the input end for analyzing whether each of the volumes exceeds a setting condition;
an adjustment module, electrically connected to the analysis module for reducing a gain value for the frequency band that exceeds the setting condition for reducing the volume of the frequency band and generating an adjusted sound signal; and
an output end, electrically connected to the adjustment module for outputting the adjusted sound signal.

11. The sound adjustment device having the hearing protection function as claimed in claim 10, wherein the adjustment module will not reduce the volume if the frequency band does not exceed the setting condition.

12. The sound adjustment device having the hearing protection function as claimed in claim 11, wherein the setting condition includes a volume threshold ranged from 60 dBA to 150 dBA.

13. The sound adjustment device having the hearing protection function as claimed in claim 12, wherein the setting condition includes a cumulative time threshold ranged from 1 second to 2 hours.

14. The sound adjustment device having the hearing protection function as claimed in claim 13, wherein when the volume threshold is larger, the cumulative time threshold is smaller, and when the volume threshold is smaller, the cumulative time threshold is larger.

15. The sound adjustment device having the hearing protection function as claimed in claim 13, wherein the setting condition is the cumulative time threshold that exceeds the volume threshold within a specific time interval.

16. The sound adjustment device having the hearing protection function as claimed in claim 13, wherein the setting condition is the number of times that exceeds the volume threshold within a specific time interval.

17. The sound adjustment device having the hearing protection function as claimed in claim 10, further comprising letting the volume of each said frequency band correspond to the same setting condition.

18. The sound adjustment device having the hearing protection function as claimed in claim 10, further comprising letting the volume of each said frequency band correspond to a different setting condition.

19. The sound adjustment device having the hearing protection function as claimed in claim 10, wherein the sound adjustment device is disposed in a sound generation device, and the sound generation device is used to generate the sound signal.

20. The sound adjustment device having the hearing protection function as claimed in claim 10, wherein the sound adjustment device is disposed in a speaker, and the speaker is used to issue the adjusted sound signal.

21. The sound adjustment device having the hearing protection function as claimed in claim 10, wherein the sound adjustment device is electrically connected between a sound generation device and a speaker, the sound generation device is used to generate the sound signal, and the speaker is used to emit the adjusted sound signal.
